(19) United States
(12) Patent Application Publication
(10) Pub. No.: US 2015/0318502 A1
(43) Pub. Date: Nov. 5, 2015

(54) TRANSPARENT ORGANIC THIN-FILM TRANSISTOR AND METHOD FOR MANUFACTURING SAME

(71) Applicant: FUJI ELECTRIC CO., LTD., Kawasaki-shi, Kanagawa (JP)

(72) Inventor: Naoyuki KANAI, Matsumoto-shi, Nagano (JP)

(73) Assignee: FUJI ELECTRIC CO., LTD., Kawasaki-shi, Kanagawa (JP)

(21) Appl. No.: 14/651,003

(22) PCT Filed: Dec. 25, 2013
(86) PCT No.: PCT/JP2013/084619

§ 371 Date: Jun. 10, 2015

(30) Foreign Application Priority Data
Jan. 7, 2013 (JP) 2013-000466

(51) Int. Cl. H01L 51/05

(52) U.S. Cl. CPC H01L 51/0545; H01L 51/052; H01L 51/055

(57) ABSTRACT

A highly transparent organic thin-film transistor that has superior transistor performance and can be applied to flexible devices includes: a transparent support substrate; a first gate electrode formed on the transparent support substrate; a second gate electrode formed on the first gate electrode; a polymeric gate-insulating layer formed on the second gate electrode; a source electrode and a drain electrode formed on the polymeric gate-insulating layer; and an organic semiconductor layer formed on the source electrode and the drain electrode.

### TECHNICAL FIELD

The present invention relates to a transparent organic thin-film transistor in which an organic semiconductor is used, and to a method for manufacturing the transistor.

### BACKGROUND ART

Organic electronics that use organic semiconductors have gained considerable attention as a next-generation technology having potential applications in thin, lightweight, and flexible devices. For example, in addition to organic electroluminescent diodes (OLED), which have already been made into products, research and development into organic field-effect transistors (OFET), which have uses in active-matrix switching elements, has made major advances in recent years.

The performance of these organic field-effect transistors is superior to the characteristics of the amorphous-silicon thin-film field-effect transistors that are currently widely used in display devices. Technologies are being developed to further improve the device characteristics and long-term stability of these transistors for practical applications.

There have been reports in the prior art; e.g., in Patent Document 1 below, of a gate-insulating layer composed of Al₂O₃, which is formed by using an O₂ plasma treatment to oxidize Al in a gate electrode, as the gate-insulating layer of an organic thin-film transistor that enables flexible organic field-effect transistors. Non-Patent Document 1 below reports using polyvinylphenol (PVP), which is a polymeric material, in the gate-insulating layers of organic thin-film transistors.

The charge transport that is necessary for driving devices in organic thin-film transistors is generated at the interface along the border between the organic semiconductor layer and the gate-insulating layer. In particular, the fact that water molecules, hydroxyl groups, and the like on the gate-insulating layer act as traps for charge transport is well known. The top of the gate-insulating layer must therefore be made highly water repellent, and, e.g., Patent Document 2 below reports using a self-organizing film to treat a gate-insulating layer composed of an inorganic oxide so as to be highly water repellent. Non-Patent Document 2 reports using a fluoropolymer, which has a large contact angle with respect to water, in the gate-insulating layer of the organic thin-film transistor.

Patent Document 3 below reports using an organic semiconductor having low absorbance of light in the visible range in order to form a highly transparent organic thin-film transistor. Providing a highly transparent organic thin-film transistor enables layering of OLEDs and other light-emitting elements, and applications in, e.g., image-displaying elements that allow letters, pictures, and the like to be displayed on window glass, vehicle windshields, and the like can be expected.

### PRIOR ART DOCUMENTS

### Patent Documents

[Patent Document 1] Japanese Patent Application Laid-Open No. 2007-214525
[Patent Document 2] Japanese Patent Application Laid-Open No. 2004-327857
[Patent Document 3] Japanese Patent Application Laid-Open No. 2009-212389

### Non-Patent Documents

[Non-Patent Document 1] Alejandro L. Briseno, Ricky J. Tseng, Mang-Mang Ling, Eduardo H. L. Falcao, Yang, Fred Wudl, and Zhenan Bao. “High-Performance Organic Monocrystalline Transistors on Flexible Substrates.” Adv. Mater., 18, pp. 2320-2324 (2006).
[Non-Patent Document 2] W. L. Kalb, T. Mathis, S. Haas, A. F. Stassen, and B. Batlogg. “Organic small molecule field-effect transistors with Cytopm gate dielectric: Eliminating gate bias stress effects.” Appl. Phys. Lett., 90, 092104 (2007).

### DISCLOSURE OF THE INVENTION

### Problems to be Solved by the Invention

However, in organic thin-film transistors in which the gate-insulating layer is composed of Al₂O₃, as described in Patent Document 1 above, problems have been presented in that Al₂O₃ has poor permeability with respect to light in the visible range, and highly transparent organic thin-film transistors cannot be obtained. In organic thin-film transistors in which polyvinylphenol (PVP) is used in the gate-insulating layer, as in Non-Patent Document 1, problems have been presented in that the PVP film is thick at approximately 1500 nm, and capacitance is poor.

In organic thin-film transistors in which the gate-insulating layer is composed of an inorganic oxide, as in Patent Document 2 above, problems have been presented in that the temperature used for forming inorganic oxides through oxidative heating is generally high at 500° C. or more, the film is thick at approximately 200 nm, and the film is not appropriate for flexible devices.

On one hand, in organic thin-film transistors in which a fluoropolymer is used in the gate-insulating layer, as in Non-Patent Document 2 above, advantages are presented in that the contact angle with respect to water is high, and water molecules and the like that obstruct interfacial carrier transport can be excluded, resulting in favorable device characteristics, but problems are presented as a result of a mechanism such that the fluoropolymer reacts with and tightly adheres to hydroxyl groups of the gate electrode, and therefore even if a metal or another electrode material having favorable conductivity is used, the metal will be inert and therefore cannot be used as the gate electrode. On the other hand, when Al or another active metal is used in the gate electrode, natural oxidation does not allow conductivity to be obtained even when the gate electrode formed to be thin at approximately 10 nm. The thickness must therefore be approximately 20 nm, and problems have been presented in that a highly transparent organic thin-film transistor cannot be manufactured.

The demand for the development of highly transparent organic thin-film transistors is thus high, but the state of the art relating to the gate electrodes and gate-insulating layers necessary for these transistors is poor.

The present invention was devised in light of the aforementioned problems, and it is an object thereof to provide a highly transparent organic thin-film transistor that has superior transistor performance and applicability to flexible devices. It is also an object thereof to provide a method for manufacturing the transistor.

### Means to Solve the Problems

In order to achieve the aforementioned objects, a transparent organic thin-film transistor of the present invention is characterized in comprising a first gate electrode formed on a transparent support substrate, an inert metal being used in the first gate electrode; a second gate electrode formed on the first gate electrode, an active metal being used in the second gate electrode; a polymeric gate-insulating layer formed on the second gate electrode, a fluoropolymer being used in the polymeric gate-insulating layer; a source electrode and a drain electrode formed on the polymeric gate-insulating layer; and an organic semiconductor layer formed on the source electrode and the drain electrode.

Another transparent organic thin-film transistor of the present invention is characterized in comprising a first gate electrode formed on a transparent support substrate, an inert metal being used in the first gate electrode; a second gate electrode formed on the first gate electrode, an active metal being used in the second gate electrode; a polymeric gate-insulating layer formed on the second gate electrode, a fluoropolymer being used in the polymeric gate-insulating layer; an organic semiconductor layer formed on the polymeric gate-insulating layer; and a source electrode and a drain electrode formed on the organic semiconductor layer.

In the transparent organic thin-film transistor of the present invention, the first gate electrode comprises one substance selected from the group consisting of Au, Pt, and Ag; and the second gate electrode comprises one substance selected from the group consisting of Al, Ti, Cr, Cu, and MgAg alloy.

A method for manufacturing a transparent organic thin-film transistor of the present invention, on one hand, is characterized in comprising a step for forming a first gate electrode using an inert metal on a transparent support substrate; a step for forming a second gate electrode using an active metal on the first gate electrode; a step for forming a polymeric gate-insulating layer using a fluoropolymer on the second gate electrode; a step for forming a source electrode and a drain electrode on the polymeric gate-insulating layer; and a step for forming an organic semiconductor layer on the source electrode and the drain electrode.

Another method for manufacturing a transparent organic thin-film transistor of the present invention is characterized in comprising a step for forming a first gate electrode using an inert metal on a transparent support substrate; a step for forming a second gate electrode using an active metal on the first gate electrode; a step for forming a polymeric gate-insulating layer using a fluoropolymer on the second gate electrode; a step for forming an organic semiconductor layer on the polymeric gate-insulating layer; and a step for forming a source electrode and a drain electrode on the organic semiconductor layer.

In the method for manufacturing a transparent organic thin-film transistor of the present invention, the first gate electrode comprises one substance selected from the group consisting of Au, Pt, and Ag; and the second gate electrode comprises one substance selected from the group consisting of Al, Ti, Cr, Cu, and MgAg alloy.

### Advantageous Effects of the Invention

According to the present invention, a configuration employed as a gate electrode of an organic thin-film transistor is such that a first gate electrode in which an inert metal is used is formed on a transparent support substrate, and a second gate electrode in which an active metal is used is layered thereon. A gate-insulating layer composed of a fluoropolymer can therefore be formed on the gate electrode while ensuring the transparency of the gate electrode. A highly transparent organic thin-film transistor that has superior transistor performance and can be applied to flexible devices can thereby be provided.

### BRIEF DESCRIPTION OF THE DRAWINGS

FIG. 1 is a schematic diagram of an embodiment of the transparent organic thin-film transistor of the present invention;

FIG. 2 is a schematic diagram of another embodiment of the transparent organic thin-film transistor of the present invention;

FIG. 3 is a schematic diagram showing the step for forming the first gate electrode in an embodiment of the method for manufacturing the transparent organic thin-film transistor of the present invention;

FIG. 4 is a schematic diagram showing the step for forming the second gate electrode in the embodiment of the method for manufacturing the transparent organic thin-film transistor of the present invention;

FIG. 5 is a schematic diagram showing the step for forming the gate-insulating layer in the embodiment of the method for manufacturing the transparent organic thin-film transistor of the present invention;

FIG. 6 is a schematic diagram showing the step for forming the source and drain electrodes in the embodiment of the method for manufacturing the transparent organic thin-film transistor of the present invention; and

FIG. 7 is a schematic diagram showing the step for forming the organic semiconductor layer in the embodiment of the method for manufacturing the transparent organic thin-film transistor of the present invention.

### BEST MODE FOR CARRYING OUT THE INVENTION

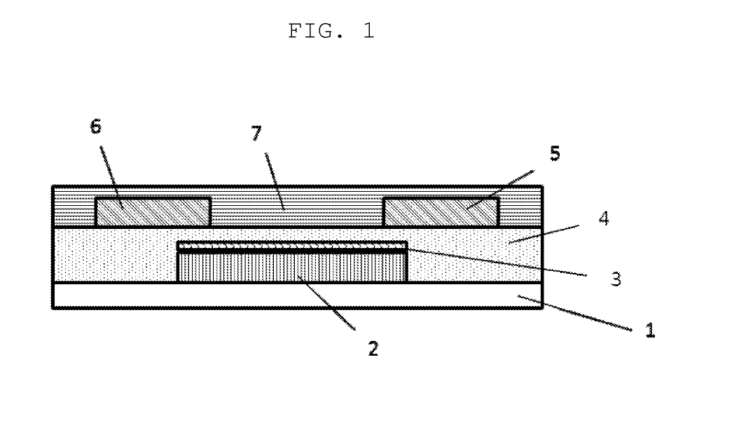

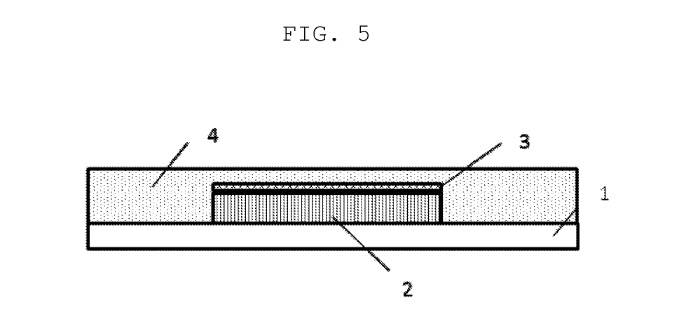

Embodiments of the transparent organic thin-film transistor of the present invention and the method for manufacturing the transistor will be described below with reference to FIGS. 1-7.

The transparent organic thin-film transistor of this embodiment is structured as a bottom-contact-type device, as shown in FIG. 1. In other words, a first gate electrode 2 is formed on a transparent support substrate 1, a second gate electrode 3 is formed on the first gate electrode 2, and a polymeric gate-insulating layer 4 is formed so as to cover the first gate electrode 2 and the second gate electrode 3. A source electrode 5 and a drain electrode 6 are formed on the polymeric gate-insulating layer 4, and these electrodes are formed separated by a predetermined interval so as to constitute a channel length of a predetermined distance. An organic semiconductor layer 7 is formed so as to cover the source electrode 5 and the drain electrode 6.

The transparent support substrate 1 should be transparent and should be durable with respect to the film-producing processes described hereinafter. Examples include glass substrates, PET (polyethylene terephthalate) films, PEN (polyethylene naphthalate) films, PC (polycarbonate) films, PES (polyethersulfone) films, and other types of film substrates.

An inert metal is used as the material of the first gate electrode 2. In other words, e.g., gold (Au), platinum (Pt), silver (Ag), or another electrode material having superior conductivity can be used. In the present specification, “inert metal” refers to metals having a standard electrode potential E° of 0.6 V or greater. The standard electrode potential herein is such that, when all of the configurational components of a battery are in a standard state, one side of the battery being a hydrogen electrode represented by the half-cell reaction of formula (1) below, and the other side being the electrode to be measured, the electromotive force of the battery measured with respect to the hydrogen electrode is defined as the standard electrode potential of the half-cell reaction of the electrode to be measured.

H⁺+e⁻=½H₂ (1)

For example, according to Chemical Handbook (Revised 5^{th} Edition, published 2004 by Maruzen Co., Ltd.), E° values are 1.83 V for Au, 1.188 V for Pt, and 0.7991 V for Ag.

The first gate electrode 2 is preferably thin to allow transparency; e.g., 5-20 nm is preferable, and 5-10 nm is more preferable. When the thickness exceeds 20 nm, transparency tends to be low. When the thickness is less than 5 nm, adequate conductivity for an electrode tends not to be obtained.

An active metal is used as the material for the second gate electrode 3. In other words, e.g., aluminum (Al), titanium (Ti), chromium (Cr), copper (Cu), a MgAg alloy, or another electrode material having favorable conductivity can be used. “Active metal” in the present specification refers to metals for which the standard electrode potential E° is less than 0.6 V. For example, according to Chemical Handbook (Revised 5th Edition, published 2004 by Maruzen Co., Ltd.), E° values are −1.676 V for Al, −1.63 V for Ti, 0.52 V for Cu, and −0.9 V for Cr.

The second gate electrode 3 is preferably thin to allow transparency; e.g., 1-10 nm is preferable, and 1-5 nm is more preferable. When the thickness exceeds 10 nm, transparency tends to be low. When the thickness is less than 1 nm, adequate conductivity for an electrode tends not to be obtained.

The reason for using an active metal in the second gate electrode 3 is to form a naturally oxidized film. In other words, due to the mechanism in which the fluoropolymer that is the material of the polymeric gate-insulating layer 4 (described hereinafter) reacts with and tightly adheres to hydroxyl groups on the gate electrode, a naturally oxidized metallic film must be formed on the substrate. Methods exist for using oxygen plasma or another treatment to actively oxidize active metals in such cases, but the number of steps also increases accordingly, which is not preferable.

A fluoropolymer that has adequate insulating properties and contains fluorine in the main chain or a side chain of the polymer is used as the material of the polymeric gate-insulating layer 4. Fluoropolymers have a large contact angle with respect to water ([i.e.,] are highly water repellent), and therefore obstruct water molecules, hydroxyl groups, and the like on the gate-insulating layer from trapping charge transfer, thereby improving transistor performance. The contact angle thereof is preferably 80° or more, and more preferably 100° or more.

The contact angle with respect to water is an index that represents the water repellence of a material and refers to the angle made by the tangent to the surface of a water droplet at the portion where the water droplet contacts the material surface, the water droplet being positioned in a static fashion on a horizontal surface of the material. The contact angle can be measured using a commercially available contact-angle gauge or the like on the basis of the θ/2 method, tangent method, curve-fitting method, or another conventionally well-known measurement method.

For the fluoropolymer, e.g., an amorphous fluorinated resin can be used. Amorphous fluorinated resins generally have superior transparency and can therefore be appropriately used in the present invention. Examples of resins that can be used include “Cytop” (brand name; contact angle with respect to water: 115°) which is commercially available from Asahi Glass Co., Ltd., and “Teflon (registered trademark) AF” (brand name; contact angle with respect to water: 105°) which is commercially available from DuPont Corp.

The thickness of the polymeric gate-insulating layer 4 is preferably 10-200 nm, and more preferably 20-100 nm. When the film is thin, a flat shape tends to be difficult to obtain, and when the film is too thick, electrostatic capacitance decreases, and the amount of carrier infused into the organic semiconductor layer 7 (described hereinafter) tends to decrease.

The electrode material for the source electrode 5 and the drain electrode 6 is not particularly limited as long as the material possesses adequate conductivity as an electrode. Gold (Au), silver (Ag), titanium (Ti), nickel (Ni), or another type of metal material can be used.

The thickness of the source electrode 5 and the drain electrode 6 can be appropriately adjusted according to the application; e.g., 20-100 nm is preferable, and 20-50 nm is more preferable. When the thickness exceeds 100 nm, time is required for manufacturing the film, and the processing time tends to lengthen. When the thickness is less than 20 nm, wiring resistance tends to increase.

A distance (channel length) L between the source electrode 5 and the drain electrode 6 is, e.g., preferably 100 μm or less and more preferably 50 μm or less. Shortening the channel length allows high-speed responsiveness, elements to be highly integrated, and other favorable properties. However, manufacturing processes for shortening the channel length generally tend to be difficult.

Conventionally known substances can be used as the organic semiconductor material of the organic semiconductor layer 7. Examples of materials that can be used include pentacene, rubrene, other p-type low-molecular-weight organic semiconductor materials, poly-3-hexylthiophene (P3HT), and other p-type high-molecular-weight organic semiconductor materials.

The thickness of the organic semiconductor layer 7 is, e.g., preferably 10-100 nm, more preferably 10-60 nm, and most preferably 20-40 nm. When the thickness exceeds 100 nm, time is required for manufacturing the film, the processing time tends to lengthen, and transparency also tends to be low. When the thickness is less than 10 nm, the organic semiconductor material may form into islands, preventing film formation, and the characteristics of the film may also deteriorate.

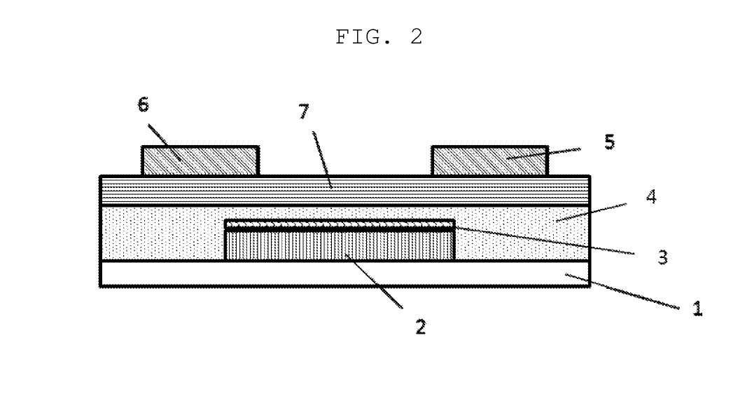

FIG. 2 shows another embodiment of the transparent organic thin-film transistor of the present invention. In this embodiment, with respect to the structure of the transparent organic thin-film transistor of the embodiment shown in FIG. 1 the organic semiconductor layer 7 is formed directly on the polymeric gate-insulating layer 4 without the source electrode and the drain electrode therebetween, and the source electrode 5 and the drain electrode 6 are formed on the organic semiconductor layer 7. The present invention can in this way also be applied to devices having a top-contact structure.

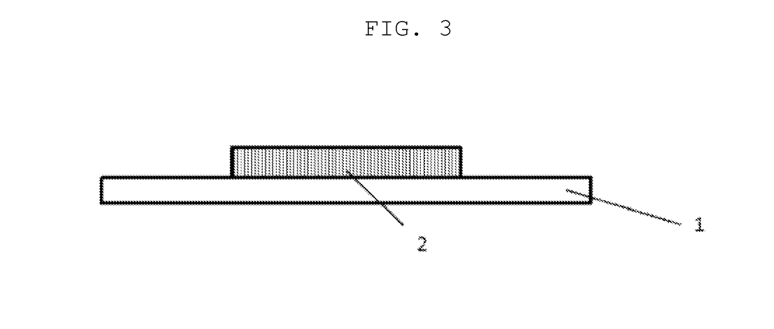

Next, an embodiment of a method for manufacturing the transparent organic thin-film transistor of the present invention will be described with reference to FIGS. 3 through 7.

First, the first gate electrode 2 is formed on the transparent support substrate 1, as shown in FIG. 3 (step for forming the first gate electrode). The first gate electrode 2 may be formed in accordance with well-known methods; e.g., resistance-heating vapor deposition, sputtering, electron-beam deposition, or other methods using the aforedescribed electrode materials can be performed.

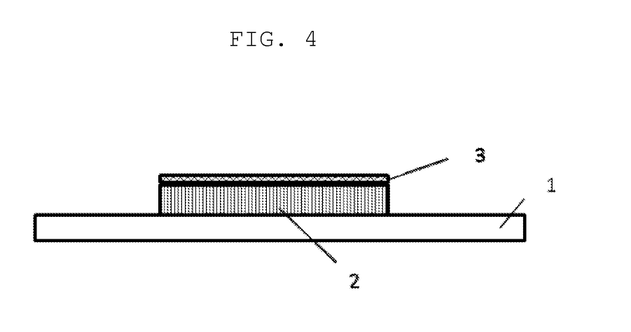

The second gate electrode 3 is then layered and formed on the first gate electrode 2, which was formed on the transparent support substrate 1, as shown in FIG. 4 (step for forming the second gate electrode). The second gate electrode 3 may be formed in accordance with well-known methods; e.g., resistance-heating vapor deposition, sputtering, electron-beam deposition, or other methods using the aforedescribed electrode materials can be performed.

The polymeric gate-insulating layer 4 is then formed on the surface of the transparent support substrate 1 on the side of where the first gate electrode 2 and the second gate electrode 3 were formed, and is formed so as to cover the first gate electrode 2 and the second gate electrode 3 (step for forming the gate-insulating layer). The polymeric gate-insulating layer 4 may be formed in accordance with well-known methods; e.g., spin coating, slit coating, dip coating, or another type of application method can be performed using the aforedescribed fluoropolymers. The top of the second gate electrode is hydrophilic due to natural oxidation. Reactions can therefore readily occur between the fluoropolymer (the silanol or carboxyl groups at the terminal ends of the polymer) and the surface of the second gate electrode 3 (in a state where hydroxyl groups are present at the surface), and the film can be formed with hydrogen bonds or covalent bonds. The surface of a gate electrode in which inert metals are used is not hydrophilic, and therefore the fluoropolymer will be repelled by the top of the gate electrode, and the film will not be readily formed.

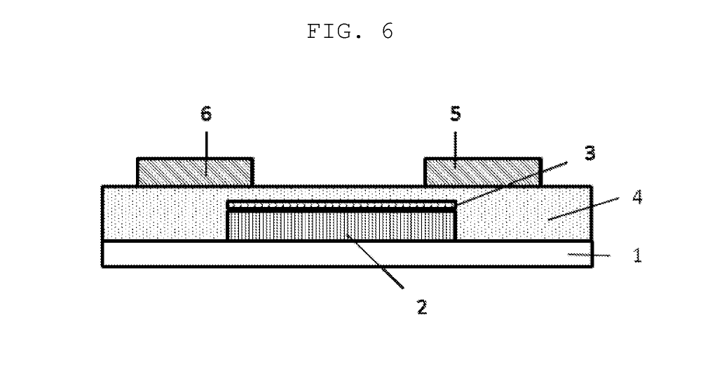

The source electrode 5 and the drain electrode 6 are then formed on the polymeric gate-insulating layer 4, as shown in FIG. 6 (step for forming source and drain electrodes). The source electrode 5 and the drain electrode 6 may be formed in accordance with well-known methods; e.g., mask vapor deposition (resistance-heating vapor deposition), sputtering, electron-beam deposition, ink jet, screen printing, spin coating, or another method can be performed using the aforedescribed electrode materials. In the case of application methods such as ink jet, screen printing, and spin coating, silver ink or another metal nanoparticle ink can be used. Photolithography can also be used.

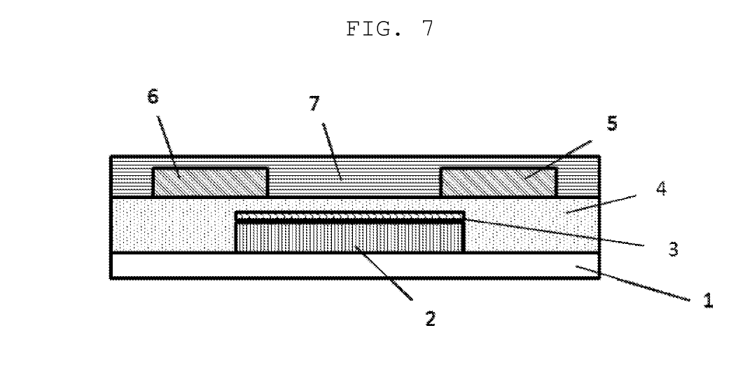

The organic semiconductor layer 7 is then formed on the surface of the polymeric gate-insulating layer 4 on the side of where the source electrode 5 and the drain electrode 6 were formed and is formed so as to cover the source electrode 5 and the drain electrode 6, as shown in FIG. 7 (step for forming the organic semiconductor layer). The organic semiconductor layer 7 may be formed in accordance with well-known methods; e.g., resistance-heating vapor deposition, ink jet, or another method can be performed using the aforedescribed organic semiconductor materials. Alternatively, a monocrystalline thin film may be formed using PVT (physical vapor transport) method and disposed as the organic semiconductor layer 7 on the surfaces of the polymeric gate-insulating layer 4 on the sides of where the source electrode 5 and the drain electrode 6 were formed.

The transparent organic thin-film transistor of the present invention can thus be manufactured. A device having a bottom-contact structure (see FIG. 1) was described as an example, but switching the order of the step for forming source and drain electrodes and the step for forming the organic semiconductor layer can be carried out to obtain a device having a top-contact structure (see FIG. 2).

### EXAMPLES

Examples will be given and the present invention will be explained in more specific detail below, but these examples do not limit the scope of the present invention.

### Example 1

The steps below were used to manufacture a bottom-contact-type organic thin-film transistor.

Quartz glass measuring 10 mm×10 mm×0.7 mm in thickness was used as a transparent support substrate. The quartz glass was mounted on a resistance-heating vapor-deposition device, Au was mask-deposited, and a first gate electrode measuring 10 nm in thickness was formed.

The resistance-heating vapor-deposition device was then used in the same manner to deposit 3 nm of Al on the first gate electrode and form the second gate electrode.

Spin coating was then used to form a gate-insulating layer measuring 50 nm in thickness on the surface of the transparent support substrate on the side of where the first and second gate electrodes were formed, where a fluoropolymer (brand name “Cytop,” Asahi Glass Co., Ltd.) was used as the high-molecular-weight insulating material. The process temperature at this time was 120° C.

The transparent support substrate on which the gate-insulating layer was formed was then mounted on a resistance-heating vapor-deposition device, Au was mask-deposited on the upper surface of the gate-insulating layer so as to have a thickness of 20 nm and a channel length of 50 μm, and a source electrode and a drain electrode were formed.

Monocrystalline (thickness: 60 nm) of pentacene (Sigma Aldrich Japan Corp.: sublimation purification performed twice) formed separately using PVT method were disposed from above the source electrode and the drain electrode formed on the gate-insulating layer, and an organic semiconductor layer was formed.

### Example 2

An organic thin-film transistor was manufactured in the same manner as Example 1, except that the Au in Example 1 was changed to Ag.

### Example 3

An organic thin-film transistor was manufactured in the same manner as Example 1, except that the Al in Example 1 was changed to Cr.

### Example 4

An organic thin-film transistor was manufactured in the same manner as Example 1, except that the Al in Example 1 was changed to Cu.

### Example 5

An organic thin-film transistor was manufactured in the same manner as Example 1, except that the Au in Example 1 was changed to Ag, and the Al was changed to Cr.

### Example 6

An organic thin-film transistor was manufactured in the same manner as Example 1, except that the Au in Example 1 was changed to Ag, and the Al was changed to Cu.

### Example 7

An organic thin-film transistor was manufactured in the same manner as Example 1, except that the transparent support substrate was a PEN film (Tenjin DuPont Films Japan Ltd., heat resistance 150° C.) in Example 1.

### Example 8

The steps below were used to manufacture a top-contact-type organic thin-film transistor.

Quartz glass measuring 10 mm×10 mm×0.7 mm in thickness was used as a transparent support substrate. The quartz glass was mounted on a resistance-heating vapor-deposition device, Au was mask-deposited, and a first gate electrode measuring 10 nm in thickness was formed.

The resistance-heating vapor-deposition device was then used in the same manner to deposit 3 nm of Al on the first gate electrode and form the second gate electrode.

Spin coating was then used to form a gate-insulating layer measuring 50 nm in thickness on the surface of the transparent support substrate on the side of where the first and second gate electrodes were formed, where a fluoropolymer (brand name “Cytop,” Asahi Glass Co., Ltd.) was used as the high-molecular-weight insulating material. The process temperature at this time was 120° C.

Monocrystalline (thickness: 60 nm) of pentacene (Sigma Aldrich Japan Corp.: sublimation purification performed twice) formed separately using PVT method were disposed on the gate-insulating layer, and an organic semiconductor layer was formed.

The transparent support substrate on which the organic semiconductor was formed was then mounted on a resistance-heating vapor-deposition device, Au was mask-deposited on the upper surface of the organic semiconductor layer so as to have a thickness of 20 nm and a channel length of 50 μm, and a source electrode and a drain electrode were formed.

### Comparative Example 1

An organic thin-film transistor was manufactured in the same manner as Example 1, except that 20 nm of Al was deposited as the gate electrode in Example 1.

### Comparative Example 2

An organic thin-film transistor was manufactured in the same manner as Example 1, except that 20 nm of Au was deposited as the gate electrode in Example 1.

Mobility was measured for the organic thin-film transistors of Examples 1 through 8 and Comparative Examples 1 and 2. Mobility was determined using a semiconductor-parameter-measuring device (Agilent Technologies, Inc.) according to the characteristics of gate voltage and drain current that were measured.

The results are given in Table 1.

TABLE 1

| | Example | Example | Example | Example | Example | Example | Example | Example | Comparative | Comparative |
|---|---|---|---|---|---|---|---|---|---|---|
| | 1 | 2 | 3 | 4 | 5 | 6 | 7 | 8 | Example 1 | Example 2 |
| Mobility | 1.2 | 1.1 | 1.0 | 1.0 | 1.1 | 1.0 | 1.0 | 0.8 | 1.2 | Not |
| (cm²/Vs) | | | | | | | | | | measurable |
| Transparent | Y | Y | Y | Y | Y | Y | Y | Y | N | N |
| device | | | | | | | | | | |
| formed/Yes | | | | | | | | | | |
| or No | | | | | | | | | | |

The results indicated that the organic thin-film transistors of Examples 1 through 8 were flexible transparent devices, and that the transistor performance thereof was extremely favorable.

On the other hand, in the case where only Al, which is an active metal, was used as a gate electrode, the transmittance was low at 20% or less, and a transparent organic thin-film transistor could not be manufactured (Comparative Example 1).

In the case where only Au, which is an inert metal, was used as a gate electrode, a reaction could not take place between the gate electrode and the fluoropolymer, which was the gate-insulating layer, and a film could not be formed (Comparative Example 2).

### KEY

| | |
|---|---|
| 1 | Transparent support substrate |
| 2 | First gate electrode |
| 3 | Second gate electrode |
| 4 | Polymeric gate-insulating layer |
| 5 | Source electrode |
| 6 | Drain electrode |
| 7 | Organic semiconductor layer |

1. A transparent organic thin-film transistor comprising:
a first gate electrode formed on a transparent support substrate, an inert metal being used in the first gate electrode;
a second gate electrode formed on the first gate electrode, an active metal being used in the second gate electrode;
a polymeric gate-insulating layer formed on the second gate electrode, a fluoropolymer being used in the polymeric gate-insulating layer;
a source electrode and a drain electrode formed on the polymeric gate-insulating layer; and
an organic semiconductor layer formed on the source electrode and the drain electrode.

2. A transparent organic thin-film transistor, characterized in comprising:
a first gate electrode formed on a transparent support substrate, an inert metal being used in the first gate electrode;
a second gate electrode formed on the first gate electrode, an active metal being used in the second gate electrode;
a polymeric gate-insulating layer formed on the second gate electrode, a fluoropolymer being used in the polymeric gate-insulating layer;
an organic semiconductor layer formed on the polymeric gate-insulating layer; and
a source electrode and a drain electrode formed on the organic semiconductor layer.

3. The transparent organic thin-film transistor according to claim 1, wherein:
the first gate electrode comprises one substance selected from a group consisting of Au, Pt, and Ag; and
the second gate electrode comprises one substance selected from a group consisting of Al, Ti, Cr, Cu, and MgAg alloy.

4. A method for manufacturing a transparent organic thin-film transistor comprising:
a step for forming a first gate electrode using an inert metal on a transparent support substrate;
a step for forming a second gate electrode using an active metal on the first gate electrode;
a step for forming a polymeric gate-insulating layer using a fluoropolymer on the second gate electrode;
a step for forming a source electrode and a drain electrode on the polymeric gate-insulating layer; and
a step for forming an organic semiconductor layer on the source electrode and the drain electrode.

5. A method for manufacturing a transparent organic thin-film transistor comprising:
a step for forming a first gate electrode using an inert metal on a transparent support substrate;
a step for forming a second gate electrode using an active metal on the first gate electrode;
a step for forming a polymeric gate-insulating layer using a fluoropolymer on the second gate electrode;
a step for forming an organic semiconductor layer on the polymeric gate-insulating layer; and
a step for forming a source electrode and a drain electrode on the organic semiconductor layer.

6. The method for manufacturing a transparent organic thin-film transistor according to claim 4, wherein:
the first gate electrode comprises one substance selected from a group consisting of Au, Pt, and Ag; and
the second gate electrode comprises one substance selected from a group consisting of Al, Ti, Cr, Cu, and MgAg alloy.

7. The transparent organic thin-film transistor according to claim 2, wherein:
the first gate electrode comprises one substance selected from a group consisting of Au, Pt, and Ag; and
the second gate electrode comprises one substance selected from a group consisting of Al, Ti, Cr, Cu, and MgAg alloy.

8. The method for manufacturing a transparent organic thin-film transistor according to claim 5, wherein:
the first gate electrode comprises one substance selected from a group consisting of Au, Pt, and Ag; and
the second gate electrode comprises one substance selected from a group consisting of Al, Ti, Cr, Cu, and MgAg alloy.
